(19) United States
(12) Patent Application Publication
(10) Pub. No.: US 2025/0081562 A1
(43) Pub. Date: Mar. 6, 2025

(54) SEMICONDUCTOR DEVICE INCLUDING SOURCE/DRAIN REGION WITH UNDERBLOCKING LAYER THEREON

(71) Applicant: Samsung Electronics Co., Ltd., Suwon-si (KR)

(72) Inventors: Keumseok Park, Slingerlands, NY (US); Kang-ill Seo, Springfield, VA (US)

(73) Assignee: Samsung Electronics Co., Ltd., Suwon-si (KR)

(21) Appl. No.: 18/434,263

(22) Filed: Feb. 6, 2024

Related U.S. Application Data
(60) Provisional application No. 63/534,954, filed on Aug. 28, 2023.

(51) Int. Cl. H01L 29/10; H01L 21/74; H01L 21/822; H01L 21/8238; H01L 27/092; H01L 29/06; H01L 29/423; H01L 29/66; H01L 29/775

(52) U.S. Cl. CPC H10D 62/371; H01L 21/74; H10D 30/014; H10D 30/43; H10D 30/6735; H10D 62/121; H10D 64/017; H10D 84/0167; H10D 84/017; H10D 84/0191; H10D 84/038; H10D 84/856; H10D 88/01

(57) ABSTRACT

Provided is a semiconductor device which includes: a substrate; a 1^{st} source/drain region above the substrate; and an under-blocking layer below the 1^{st} source/drain region, wherein the under-blocking layer faces the substrate, and comprises one or more insulation materials, wherein the under-blocking layer is disposed below a level of a top surface of the substrate.

### CROSS-REFERENCE TO RELATED APPLICATION

This application is based on and claims priority from U.S. Provisional Application No. 63/534,954 filed on Aug. 28, 2023 in the U.S. Patent and Trademark Office, the disclosure of which is incorporated herein in its entirety by reference.

### BACKGROUND

### 1. Field

Apparatuses and methods related to one or more embodiments of the disclosure relate to a semiconductor device in which an under-blocking layer is formed on a source/drain region.

### 2. Description of the Related Art

A 3D-stacked semiconductor device including a 1^{st} transistor and a 2^{nd} transistor stacked above the 1^{st} transistor has been introduced in response to increased demand for an integrated circuit having a high device density and performance. Each of the two transistors in the 3D-stacked semiconductor device may be a fin field-effect transistor (FinFET), a nanosheet transistor or any other type of transistor, not being limited thereto. The FinFET has one or more horizontally arranged vertical fin structures as a channel structure of which at least three surfaces are surrounded by a gate structure, and the nanosheet transistor is characterized by one or more nanosheet channel layers vertically stacked on a substrate as a channel structure and a gate structure surrounding all four surfaces of each of the nanosheet channel layers. The nanosheet transistor is referred to as gate-all-around (GAA) transistor, or as a multi-bridge channel field-effect transistor (MBCFET).

However, as a contact-poly-pitch (CPP) of a 3D-stacked semiconductor device decreases to further increase the device density, preventing or reducing current leakage from a source/drain region to a substrate in the 3D-stacked semiconductor device presents greater challenges. The current leakage may deteriorate electrical characteristics of a semiconductor device such as a threshold voltage, increase power consumption, and generate signal interference and cross-talk, not being limited thereto.

A punch-through-stop (PTS) implementation may be performed on a substrate below a source/drain region in a 3D-stacked semiconductor device to prevent or reduce current leakage from the source/drain region into the substrate. In the PTS implementation, the substrate may be doped with impurities having a polarity opposite to impurities doped in the source/drain region formed above the substrate. For example, boron (B) may be doped in a substrate below an n-type source/drain region doped with phosphorous (P) to prevent or reduce current leakage from the source/drain region into the substrate. However, the PTS implementation does not provide sufficient prevention or reduction of the current leakage, and also the process thereof is difficult and complicated.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

Embodiments of the disclosure provide a semiconductor device in which an under-blocking layer is formed on a source/drain region to prevent current flow or leakage from the source/drain region to a substrate.

According to an embodiment, there is provided a semiconductor device which may include: a substrate; a 1^{st} source/drain region above the substrate; and an under-blocking layer below the 1^{st} source/drain region, the under-blocking layer facing the substrate.

According to an embodiment, the under-blocking layer may be formed in the substrate, and may include: a 1^{st} portion below the 1^{st} source/drain region, vertically overlapping the 1^{st} source/drain region; a 2^{nd} portion at a 1^{st} side of the 1^{st} source/drain region, not vertically overlapping the 1^{st} source/drain region; and a 3^{rd} portion at a 2^{nd} side of the 1^{st} source/drain region, not vertically overlapping the 1^{st} source/drain region.

According to an embodiment, there is provided a semiconductor device which may include: a substrate; a 1^{st} source/drain region above the substrate; and an under-blocking layer configured to prevent or reduce current flow from the 1^{st} source/drain region to the substrate.

According to an embodiment, there is provided a method of manufacturing a semiconductor device. The method may include: forming a substrate recess in a substrate; forming an under-blocking layer in the substrate recess; and forming a source/drain region on the under-blocking layer.

According to an embodiment, the forming the substrate recess may include: forming an initial recess in the substrate; and etching the substrate from the initial recess in a (100) plane direction and a (110) plane direction.

### BRIEF DESCRIPTION OF DRAWINGS

Example embodiments of the disclosure will be more clearly understood from the following detailed description taken in conjunction with the accompanying drawings in which:

FIG. 1 illustrates a 3D-stacked semiconductor device including an under-blocking layer formed on a source/drain region, according to an embodiment;

FIGS. 2A-2M illustrate intermediate semiconductor devices obtained after respective steps of forming a 3D-stacked semiconductor device including an under-blocking layer formed on a source/drain region, according one or more embodiments;

FIG. 3 illustrates a flowchart of manufacturing a semiconductor device including an under-blocking layer formed on a source/drain region, according one or more embodiments; and

FIG. 4 is a schematic block diagram illustrating an electronic device including at least one of the 3D-stacked semiconductor devices shown in FIGS. 1 and 2A-2M and the semiconductor device described in reference to FIG. 3, according to one or more embodiments.

### DETAILED DESCRIPTION

The embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure. For example, even if matters described in a specific example or embodiment are not described in a different example or embodiment thereto, the matters may be understood as being related to or combined with the different example or embodiment, unless otherwise mentioned in descriptions thereof. In addition, it should be understood that all descriptions of principles, aspects, examples, and embodiments of the disclosure are intended to encompass structural and functional equivalents thereof. In addition, these equivalents should be understood as including not only currently well-known equivalents but also equivalents to be developed in the future, that is, all devices invented to perform the same functions regardless of the structures thereof. For example, source/drain regions, channel layers, sacrificial layers, gate structures, and isolation layers described herein may take a different type or form as long as the disclosure can be applied thereto.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “left,” “right,” “lower-left,” “lower-right,” “upper-left,” “upper-right,” “central,” “middle,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, an element described as “below” or “beneath” another element would then be oriented “above” the other element. Thus, the term “below” can encompass both an orientation of above and below. The semiconductor device may be otherwise oriented (rotated 90 degrees or at other orientations) and the spatially relative descriptors used herein interpreted accordingly. As another example, when elements referred to as a “left” element and a “right” element” may be a “right” element and a “left” element when a device or structure including these elements are differently oriented. Thus, in the descriptions herebelow, the “left” element and the “right” element may also be referred to as a “1^{st}” element or a “2^{nd}” element, respectively, as long as their structural relationship is clearly understood in the context of the descriptions. Similarly, the terms a “lower” element and an “upper” element may be respectively referred to as a “1^{st}” element and a “2^{nd}” element with necessary descriptions to distinguish the two elements.

It will be understood that, although the terms “1^{st},” “2^{nd},” “3^{rd},” “4^{th},” “5^{th},” “6^{th},” etc. may be used herein to describe various elements, these elements should not be limited by these terms. These terms are only used to distinguish one element from another element. Thus, a 1^{st} element discussed below could be termed a 2^{nd} element without departing from the teachings of the disclosure.

As used herein, expressions such as “at least one of,” when preceding a list of elements, modify the entire list of elements and do not modify the individual elements of the list. For example, the expression, “at least one of a, b and c,” should be understood as including only a, only b, only c, both a and b, both a and c, both b and c, or all of a, b and c. Herein, when a term “same” is used to compare a dimension of two or more elements, the term may cover a “substantially same” dimension.

It will be also understood that, even if a certain step or operation of manufacturing an apparatus or structure is described later than another step or operation, the step or operation may be performed later than the other step or operation unless the other step or operation is described as being performed after the step or operation.

Many embodiments are described herein with reference to cross-sectional views that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. Various regions illustrated in the figures are schematic in nature and their shapes are not intended to illustrate the actual shape of a region of a device and are not intended to limit the scope of the disclosure. Further, in the drawings, the sizes and relative sizes of layers and regions may be exaggerated for clarity.

For the sake of brevity, conventional elements, structures or layers of a semiconductor device including a nanosheet transistor and materials forming the same may or may not be described in detail herein. For example, a certain isolation layer or structure of a semiconductor device and materials forming the same may be omitted herein when this layer or structure is not related to the novel features of the embodiments. Also, descriptions of materials forming well-known structural elements of a semiconductor device may be omitted herein when those materials are not relevant to the novel features of the embodiments.

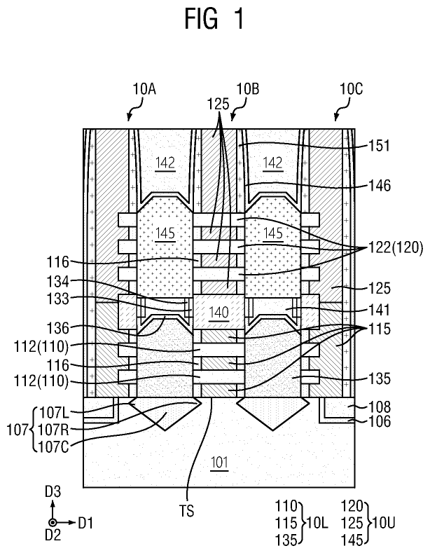

FIG. 1 illustrates a 3D-stacked semiconductor device including an under-blocking layer formed on a source/drain region, according to an embodiment.

FIG. 1 is a cross-section view of the 3D-stacked semiconductor device in a D1 direction or which is a channel-length direction in which current flows between two source/drain regions connected to each other through a channel structure, and a D2 direction is a channel-width direction that horizontally intersects the D1 direction. A D3 direction is a channel-thickness direction that vertically intersects the D1 and D2 directions.

Referring to FIG. 1, a 3D-stacked semiconductor device 10 may include a 1^{st} semiconductor stack 10A, a 2^{nd} semiconductor stack 10B, and a 3^{rd} semiconductor stack 10C on a substrate 101. The substrate 101 may be a silicon (Si) substrate, and additionally or alternatively, it may include other materials such as silicon germanium (SiGe), or silicon carbide (SiC), not being limited thereto.

Each of the semiconductor stacks 10A-10C may include a 1^{st} channel structure 110 and a 2^{nd} channel structure 120 formed above the 1^{st} channel structure 110. The 1^{st} channel structure 110 may be surrounded by a 1^{st} gate structure 115, and the 2^{nd} channel structure 120 may be surrounded by a 2^{nd} gate structure 125. The 1^{st} channel structure 110 may include a plurality of 1^{st} channel layers 112, and the 2^{nd} channel structure 120 may include a plurality of 2^{nd} channel layers 122. These channel layers may each be a thin nanosheet, nanowire or nanoribbon formed based on the substrate 101, and thus, a transistor including these channel layers may be referred to as a nanosheet transistor. The channel layers 112 and 122 may each be formed of the same material, for example, silicon (Si) included in the substrate 101. Here, the 1^{st} and 2^{nd} channel structures 110 and 120 included in each of the 1^{st} and 3^{rd} semiconductor stacks 10A and 10C may be used to form source/drain regions as described later, but may not function as a channel of a transistor in some instances. In this regard, the 1^{st} and 3^{rd} semiconductor stacks 10A and 10C may each be a dummy transistor structure, and may be removed in the 3D-stacked semiconductor device 10 in its completed form. In other instances (not shown for simplicity), the 1^{st} and 3^{rd} semiconductor stacks 10A and 10C may be configured to be active regions of additional transistors, connecting even more source/drain regions.

The 1^{st} gate structure 115 and the 2^{nd} gate structure 125 may each include a gate dielectric layer, a work-function metal layer, and a gate electrode. The gate dielectric layer may include an interfacial layer formed of an oxide material such as silicon oxide (SiO), silicon dioxide (SiO₂), and/or silicon oxynitride (SiON), nblt. The gate dielectric layer may further include an high-k layer formed of a high-k material such as Hf, Al, Zr, La, Mg, Ba, Ti, Pb, and/or a combination thereof, not being limited thereto. The work-function metal layer may be formed of a metal such as Cu, Al, titanium (Ti), tantalum (Ta), W, Co, TiN, WN, TiAl, TiAlN, TaN, titanium carbide (TiC), TaC, TiAlC, TaCN, TaSiN, or a combination thereof, not being limited thereto. However, the two gate structures 115 and 125 may be have different work-function metal layers having different threshold voltages, respectively. For example, when the 1^{st} and 2^{nd} transistors 10L and 10U are of n-type and p-type, respectively, the 1^{st} gate structure 115 of the 1^{st} transistor 10L may include a work-function metal layer formed of Al or TiC, and the 2^{nd} gate structure 125 of the 2^{nd} transistor 10U may include a work-function metal layer formed of TiN. The gate electrode may be formed of Cu, W, Al, Ru, Mo, Co, and/or a combination thereof, not being limited thereof.

The gate structures 115 and 125 in each of the semiconductor stacks 10A-10C may be protected by a gate spacer 151 which prevents the gate structures from being oxidized in a process of manufacturing the 3D-stacked semiconductor device 10. The gate spacers 151 may be formed of silicon oxide or silicon nitride (e.g., SiO₂, SiN, SiBCN, SiCN, SiOC, SiOCN, etc.), not being limited thereto.

1^{st} source/drain regions 135 and 2^{nd} source/drain regions 145 may be formed between the 1^{st} semiconductor stack 10A and the 2^{nd} semiconductor stack 10B, and between the 2^{nd} semiconductor stack 10B and the 3^{rd} semiconductor stack 10C. The 1^{st} source/drain regions 135 may be formed above the substrate 101, and connected to each other through the 1^{st} channel structure 110 surrounded by the 1^{st} gate structure 115 in the 2^{nd} semiconductor stack 10B, to form a 1^{st} transistor 10L (e.g., a lower transistor). The 2^{nd} source/drain regions 145 may be connected to each other through the 2^{nd} channel structure 120 surrounded by the 2^{nd} gate structure 125 in the 2^{nd} semiconductor stack 10B, to form a 2^{nd} transistor 10U (e.g., an upper transistor). As will be described later, the 1^{st} source/drain regions may be formed by epitaxially growing silicon (Si) included in the 1^{st} channel layers 112, and the 2^{nd} source/drain regions may be formed by epitaxially growing silicon (Si) included in the 2^{nd} channel layers 122.

The 1^{st} source/drain regions 135 may be formed of silicon (Si) doped with n-type impurities such as phosphorus (P), arsenic (As), antimony (Sb), etc. to form the 1^{st} transistor 10L as an n-type transistor. The 2^{nd} source/drain regions 145 may be formed of silicon (Si) or silicon germanium (SiGe) doped with p-type impurities such as boron (B), gallium (Ga), indium (In), etc., to form the 2^{nd} transistor 10U as a p-type transistor. The disclosure is not limited thereto, however, and the 1^{st} transistor 10L may be formed as a p-type and the 2^{nd} transistor 10U may be formed as an n-type, or both of the 1^{st} and 2^{nd} transistors 10L and 10U may be formed as either a p-type or an n-type.

The source/drain regions 135 and 145 may be isolated from the gate structures 115 and 125 by inner spacers 116 formed therebetween. The inner spacer 116 may be formed of one or more dielectric materials such as silicon nitride (e.g., SiN, SiBCN, SiCN, SiOCN, etc.) or silicon oxide (SiO, SiO₂, etc.) which may be the same or different from the material forming the gate spacer 151. The dielectric materials may be electrical insulation materials.

An under-blocking layer 107 may be formed on each of the 1^{st} source/drain regions 135. For example, the under-blocking layer 107 may be formed on a bottom surface of the 1^{st} source/drain region 135 facing the substrate 101, between the 1^{st} source/drain region and the substrate 101. The under-blocking layer 107 may prevent or reduce current flow or leakage from the 1^{st} source/drain region 135 into the substrate when the current flows between the 1^{st} source/drain regions 135. The under-blocking layer 107 may be formed such that a lower portion of the source/drain region 135 is surrounded or enclosed by the under-blocking layer 107 in the substrate 101. The under-blocking layer 107 may be formed at a level of a top surface TS of the substrate 101 which may, in some instances, contact or may be coplanar with a bottom surface of the 1^{st} gate structure 115 and a bottom surface of the lowermost inner spacer among the inner spacers 116, or a bottom surface of a bottom dielectric isolation (BDI) layer which may be formed between the 1^{st} gate structure 115 and the substrate 101.

The under-blocking layer 107 may include a 1^{st} portion 107C, which is a central portion, directly below the bottom surface of the 1^{st} source/drain region 135, and 2^{nd} and 3^{rd} portions 107L and 107R, side portions, directly below the lowermost inner spacers 116. In some cases, the 1^{st} portion 107C may take a pointed or triangular shape of edging into the substrate 101 from the bottom surface of the 1^{st} source/drain region 135 such that a length of the 1^{st} portion 107C (in the D1 direction) decreases in a downward D3 direction. The 2^{nd} portion 107L may take a triangular or pointed shape of edging into the substrate 101 such that a thickness of the 2^{nd} portion 107L (in the D3 direction) decreases in a leftward D1 direction from the lower portion of the 1^{st} source/drain region 135. The 3^{rd} portion 107R may take a triangular or pointed shape of edging into the substrate 101 such that a thickness (in the D3 direction) of the 3^{rd} portion 107R decreases in a rightward D1 direction from the lower portion of the 1^{st} source/drain region 135. However, the disclosure is not limited thereto, and the shape of the under-blocking layer 107 may take a different shape or form as long as it surrounds or encloses the lower portion of the source/drain region 135.

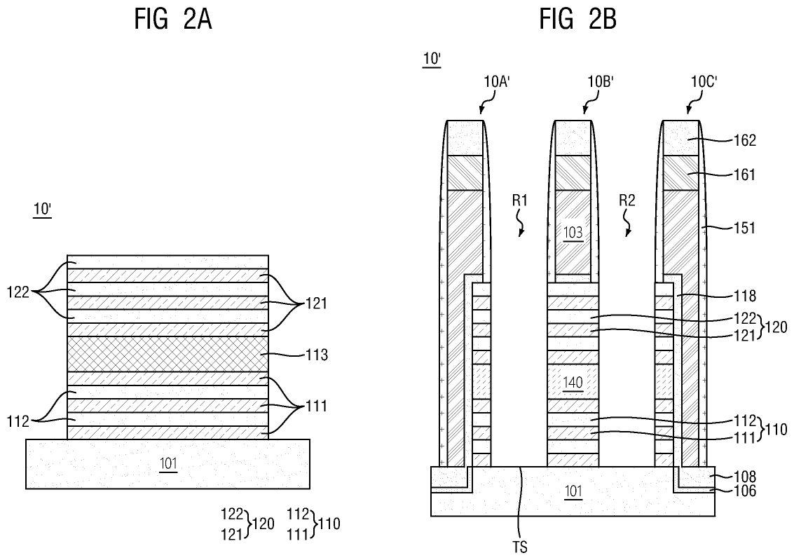

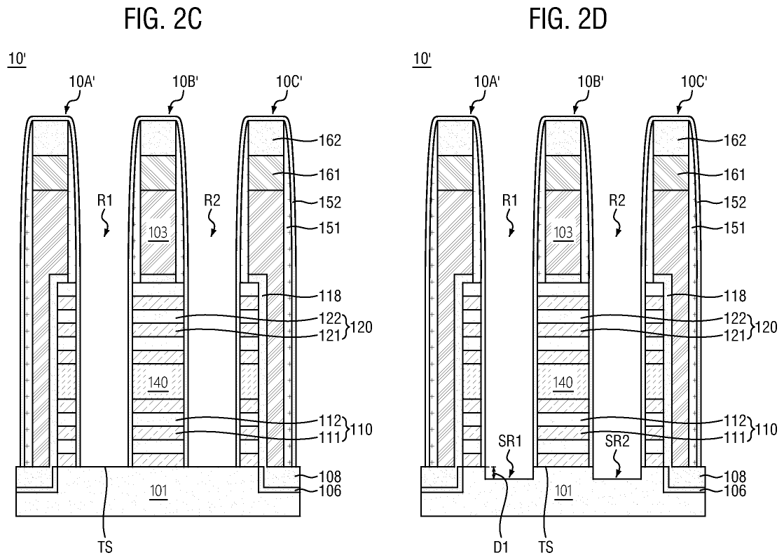

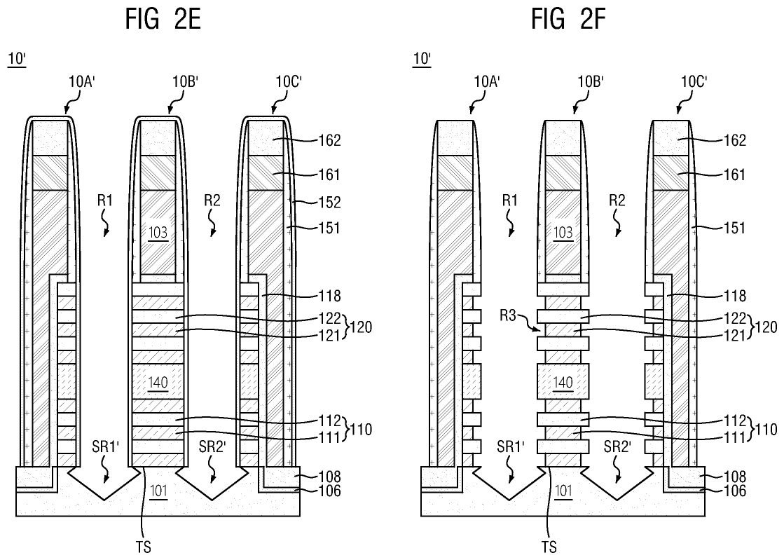

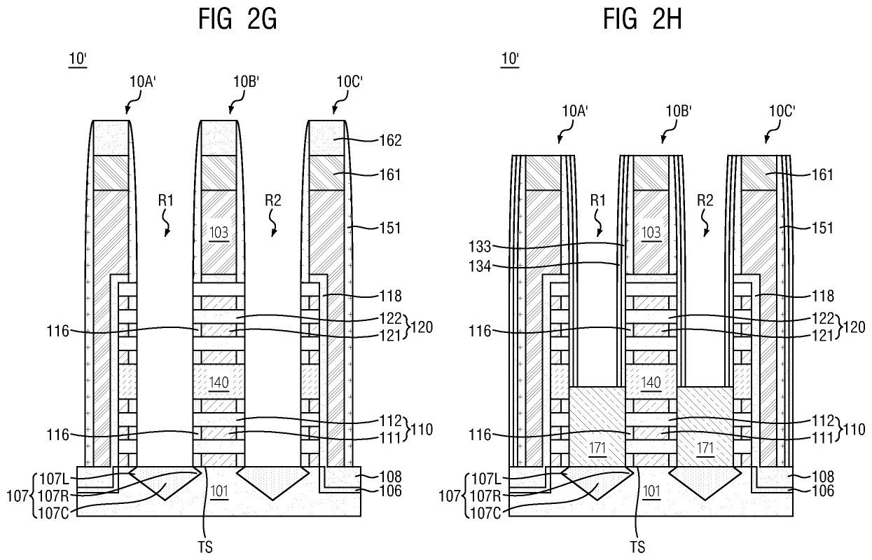

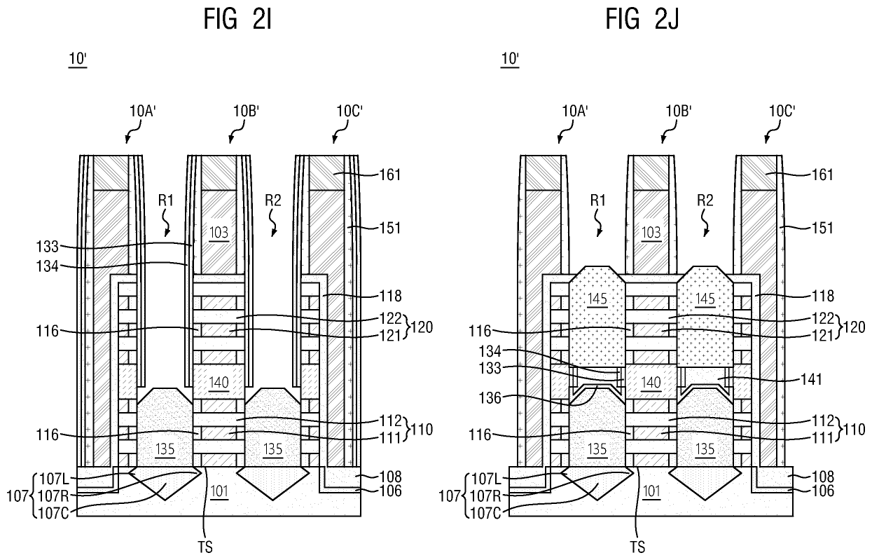

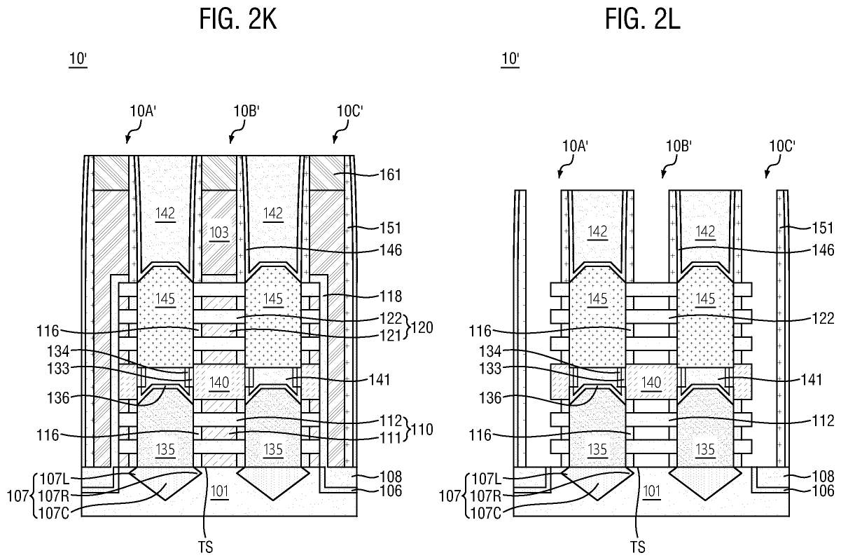

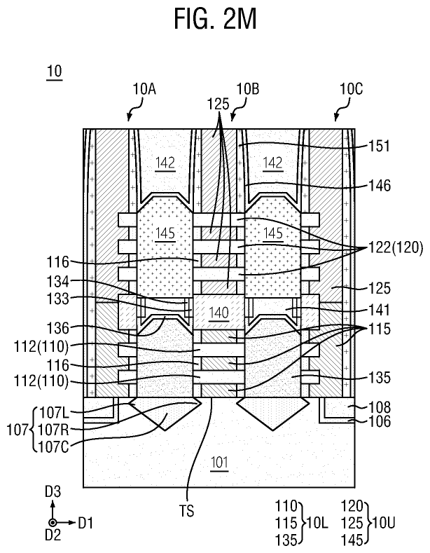

The under-blocking layer 107 may be formed along with the inner spacers 116 in the process of manufacturing the 3D-stacked semiconductor device 10 as will be described later in reference to FIGS. 2A-2M, and thus, may include the same or similar material, e.g., silicon nitride, forming the inner spacers 116. For example, the under-blocking layer 107 may be formed at the same time as the inner spacers 116 in a same process or operation.

As the under-blocking layer 107 is a physical structural barrier layer, current flow or leakage from the 1^{st} source/drain regions 135 to the substrate 101 may be more effectively prevented or reduced in the 3D-stacked semiconductor device 10, and may be easily implemented in the process of manufacturing the 3D-stacked semiconductor device compared to the punch-through-stop (PTS) implementation that is described earlier.

The 3D-stacked semiconductor device may also include a shallow trench isolation (STI) structure 108 formed on upper-left and upper-right edges of the substrate 101 with an STI liner 106 therebetween. The STI structure 108 may isolate the 3D-stacked semiconductor device 10 from one or more adjacent semiconductor devices or circuit elements. The STI structure 108 may include silicon oxide (e.g., SiO or SiO₂), not being limited thereto, and the STI liner 106 may include silicon nitride (e.g., SiN or Si₃N₄), not being limited thereto.

A 1^{st} isolation structure 141 may be formed between the 1^{st} source/drain region 135 and the 2^{nd} source/drain region 145, and a 2^{nd} isolation structure 142 may be formed above the 2^{nd} source/drain regions 145. These isolation structures may be formed to isolate the source/drain regions 135 and 145 from each other or from other circuit elements. The isolation structures 141 and 142 may both be formed of silicon oxide (e.g., SiO or SiO₂), not being limited thereto. Further, a 1^{st} protection layer 136 may be formed on the 1^{st} source/drain regions 135 at least to prevent oxidation thereof from the 1^{st} isolation structure 141, and a 2^{nd} protection layer 146 may be formed on the 2^{nd} source/drain regions 145 at least to prevent oxidation thereof from the 2^{nd} isolation structure 142.

A middle isolation layer 140 may be formed between the 1^{st} gate structure 115 and the 2^{nd} gate structure 125 to isolate these two gate structures in the 2^{nd} semiconductor stack 10B. The middle isolation layer 140 may be formed of a dielectric material such as silicon nitride (e.g., SiBCN, SiCN, SiOCN, SiN, etc.), not being limited thereto. Between the middle isolation layer 140 and the 1^{st} isolation structure 141 may be formed a 1^{st} blocking layer 133 and a 2^{nd} blocking layer 134 that are used to cover the 2^{nd} channel structure 120 when the 1^{st} source/drain regions are formed in the process of manufacturing the 3D-stacked semiconductor device 10. The 1^{st} blocking layer 133 may include a material such as a silicon oxide (e.g., SiO, SiO₂, etc.), and the 2^{nd} blocking layer 134 may include a material such as a silicon nitride (e.g., SiN, Si₃N₄, etc.), not being limited thereto.

Herebelow, a method of manufacturing a 3D-stacked semiconductor device including an under-blocking layer formed on a source/drain region is described.

FIGS. 2A-2M illustrate intermediate semiconductor devices obtained after respective steps of forming a 3D-stacked semiconductor device including an under-blocking layer formed on a source/drain region, according one or more embodiments.

As the 3D-stacked semiconductor device manufactured through the respective steps as shown in FIGS. 2A-2M may be the same as or may correspond to the 3D-stacked semiconductor device 10 shown in FIG. 1, duplicate descriptions thereof may be omitted and the same reference numbers may be used in the descriptions herebelow.

Referring to FIG. 2A, an initial semiconductor stack 10′ may be formed by epitaxially growing a plurality of semiconductor layers on a substrate 101 in the order of a 1^{st} channel structure 110, a middle sacrificial layer 113, and a 2^{nd} channel structure 120.

The 1^{st} channel structure 110 may include 1^{st} sacrificial layers 111 and 1^{st} channel layers 112 vertically stacked in an alternating manner on the substrate 101. A 1^{st} channel layer 112 may be interposed between two adjacent 1^{st} sacrificial layers 111. On the 1^{st} channel structure 110 may be formed the middle sacrificial layer 113. The 2^{nd} channel structure 120 may include 2^{nd} sacrificial layers 121 and 2^{nd} channel layers 122 vertically stacked in an alternating manner on the middle sacrificial layer 113. A 2^{nd} channel layer 122 may be interposed between two adjacent 2^{nd} sacrificial layer 121.

While the substrate 101 and the channel layers 112 and 122 are formed of silicon (Si), the sacrificial layers 111, 113 and 121 may be formed of silicon germanium (SiGe) with respective Ge concentrations therein. The 1^{st} and 2^{nd} sacrificial layers 111 and 121 may have the same Ge concentration (e.g., 25%), and the middle sacrificial layer 113 may have a higher Ge concentration (e.g., 45%) than the 1^{st} and 2^{nd} sacrificial layers 111 and 121 so that the middle sacrificial layer can have an etch selectivity against the 1^{st} and 2^{nd} sacrificial layers 111 and 121 as well as the channel layers 112 and 122 in a later step of manufacturing a 3D-stacked semiconductor device. Here, the sacrificial layers 111, 113 and 121 are termed as such because these layers will be removed and replaced by other layers or structures in later steps of manufacturing the 3D-stacked semiconductor device.

Referring to FIG. 2B, the substrate 101 may be patterned to form a shallow trench isolation (STI) structure 108 that will isolate a semiconductor device formed on the substrate 101 from an adjacent device or circuit element. An STI liner 106 may be formed before the STI structure 108 is formed on the substrate 101.

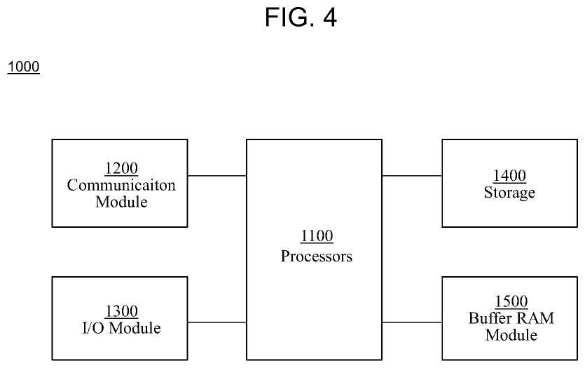

A barrier layer 118 may be formed to surround the initial semiconductor stack 30′ of FIG. 4A to protect at least the channel layers 112 and 122 in subsequent processes of manufacturing a 3D-stacked semiconductor device, and then, an initial dummy gate structure with hard mask patterns 161 and mask protection structures 162 thereon may be formed on the initial semiconductor stack 30′ with the barrier layer 118 therebetween. The initial dummy gate structure and the barrier layer 118 may be patterned through, for example, directional dry etching such as reactive ion etching (RIE), based on the hard mask patterns 161 to obtain three dummy gate structures 103 on the initial semiconductor stack 30′, and gate spacers 151 may be formed on side surfaces of the dummy gate structures 103. Further, the initial semiconductor stack 10′ may be patterned through, for example, drying etching (e.g., RIE), to form three intermediate semiconductor stacks 10A′-10C′ based on the hard mask patterns 161, the mask protection structures 162 and the gate spacers 151 as a masking structure. Also, the middle sacrificial layer 113 may be removed based on the masking structure through dry etching or wet etching using, for example, hydrofluoric acid (HF) that may selectively etch the middle sacrificial layer 113 including a higher Ge concentration against the 1^{st} and 2^{nd} sacrificial layers 111 and 121 having a lower Ge concentration and the channel layers 112 and 122. In a space provided by the removal of the middle sacrificial layer 113 may be filled in with a middle isolation layer 140 formed of silicon nitride (e.g., SiN, SiBCN, SiCN, SiOCN, etc.), not being limited thereto, through, for example, atomic layer deposition (ALD), physical vapor deposition (PVD), plasma enhanced atomic layer deposition (PEALD), chemical vapor deposition (CVD), plasma enhanced chemical vapor deposition (PECVD), or a combination thereof, not being limited thereto.

The dummy gate structures 103 may include a material such as amorphous silicon (a-Si) or polysilicon (p-Si), not being limited thereto. The 1^{st} barrier layer 118 may be formed of silicon oxide (e.g., SiO or SiO₂), not being limited thereto. The hard mask patterns 161 may include a dielectric material such as silicon nitride (SiN), titanium nitride (TiN), or silicon oxynitride (SiON), not being limited thereto. The mask protection structures 162 may be formed of silicon oxide (e.g., SiO or SiO₂), not being limited thereto. The gate spacers 151 may be formed of silicon nitride (e.g., SiN, SiBCN, SiCN, SiOCN, etc.), not being limited thereto. The mask protection structures 162 may protect the hard mask patterns 161 when the gate spacers 151 are formed on side surfaces of the dummy gate structures 103.

The patterning of the initial semiconductor stack 10′ in this step may be performed through, for example, dry etching such as reactive ion etching (RIE) such that two recesses R1 and R2 are formed to divide the initial semiconductor stack 10′ into the intermediate semiconductor stacks 10A′-10C′. By this patterning, each of the intermediate semiconductor stacks 10A′-10C′ may have side surfaces of the 1^{st} channel structure 110, the middle isolation layer 140, and the 2^{nd} channel structure 120 in the recesses R1 and R2. In a later step, source/drain regions will be formed in the recesses R1 and R2 based on the channel structures 110 and 120.

The gate spacer 151 may be formed to prevent the dummy gate structures 103 and gate structures that may replace the dummy gate structures 103 in a later step from being oxidized in the subsequent steps, and isolate these gate structures from other circuit elements. The 1^{st} barrier layer 118 may be formed to protect the 1^{st} and 2^{nd} channel structures 110 and 120 when the dummy gate structures 103 are replaced by the gate structure in a later step.

Referring to FIG. 2C, a 2^{nd} barrier layer 152 may be formed to surround each of the intermediate semiconductor stacks 10A′-10C′ to protect the gate spacers 151, the channel structures 110, 120 and the middle isolation layer 140 from a subsequent step of patterning the substrate 101 through the recesses R1 and R2.

The 2^{nd} barrier layer 152 may be conformally formed on the intermediate semiconductor stacks 10A′-10C′ including the top surface of the substrate 101 exposed through the recesses R1 and R2, and then, a portion thereof on the top surface of the substrate 101 may be removed to expose the top surface of the substrate 101 again through the recesses R1 and R2. Thus, the 2^{nd} barrier layer 152 may remain only on the intermediate semiconductor stacks 10A′-10C′including the side surfaces of the gate spacers 151, the channel structures 110, 120 and the middle isolation layer 140 exposed through the recesses R1 and R2.

The formation of the 2^{nd} barrier layer 152 may be performed through, for example, atomic layer deposition (ALD) of silicon oxide (e.g., SiO or SiO₂) followed by dry etching, not being limited thereto.

Referring to FIG. 2D, the top surface of the substrate 101 exposed through the recesses R1 and R2 may be etched down by a predetermined depth (or thickness) DT1 from a top surface TS of the substrate 101 through, for example, dry etching, not being limited thereto.

By the etching operation in this step, substrate recesses SR1 and SR2 may be formed in substrate 101, based on which a subsequent etching operation and formation of an under-blocking layer is to be formed in a later step.

Referring to FIG. 2E, an additional etching operation is performed on the substrate recesses SR1 and SR2 so that the substrate recesses SR1 and SR2 may be changed to extended substrate recesses SR1′ and SR2′ to have a cut-diamond or sigma shape, respectively, in the substrate 101.

The additional etching operation in this step may be performed through, for example, wet etching using a wet etchant such as tetramethylammonium hydroxide (TMAH) and/or ammonium hydroxide (NH₄OH), not being limited thereto, so that each of the substrate recesses SR1 and SR2 may be etched in the (100) plane direction (downward) and the (110) plane direction (leftward and rightward) to form the extended substrate recesses SR1′ and SR2′, respectively, having a cut-diamond or sigma shape in the substrate 101. In a later step, an under-blocking layer is to be formed in each of the extended substrate recesses SR1′ and SR2′.

Referring to FIG. 2F, the 2^{nd} barrier layer 152 formed in the previous step (FIG. 2C) may be removed, through, for example, etch stripping, not being limited thereto. Further, a selective etching operation may be performed on the side surfaces of the 1^{st} sacrificial layers 111, the middle isolation layer 140, and the 2^{nd} sacrificial layers 121 of each of the intermediate semiconductor stacks 10A′-10C′ exposed though the recesses R1 and R2.

The selective etching operation in this step may pull back a portion of each of the sacrificial layers 111 and 121 from the side surface thereof exposed through the recesses R1 and R2. For example, dry etching or wet etching may be applied using, for example, hydrofluoric acid (HF), which etches a Ge or SiGe component in the sacrificial layers 111 and 121 without attacking the channel layers 112 and 122 formed of silicon (Si). Due to the selective etching operation in this step, a side recess R3 may be formed at each side surface of the sacrificial layers 111 and 121.

Referring to FIG. 2G, inner spacers 116 may be formed in the side recesses R3 at the sacrificial layers 111 and 121 in each of the intermediate semiconductor stacks 10A′-10C′. At the same time, an under-blocking layer 107 may be formed in each of the extended substrate recesses SR1′ and SR2′ by partially filling the same material forming the inner spacers 116, which may be silicon nitride.

To form the under-blocking layer 107, a dielectric material such as silicon nitride may be filled in a lower portion of each of the substrate recesses SR1′ and SR2′ obtained from the etching in the (100) plane direction in the previous step, so that a 1^{st} portion 107C of the under-blocking layer 107 may be formed in the substrate 101. The silicon nitride may also be filled in two opposite side portions of each of the substrate recesses SR1′ and SR2′ formed by the etching in the (110) plane directions in the previous step, so that a 2^{nd} portion 107L and a 3^{rd} portion 107R of the under-blocking layer 107 may be formed in the substrate 101. Due to the 2^{nd} and 3^{rd} portions 107L and 107R, the length of the under-blocking layer 107 may be greater than the length of the 1^{st} source/drain region 135 in the D1 direction, by which the current leakage from the 1^{st} source/drain region 135 may be better prevented.

The formation of the inner spacers 116 and the under-blocking layer 107 may be performed through, for example, ALD, PVD, PEALD, CVD, PECVD, or a combination thereof, followed by dry etching and/or wet etching, not being limited thereto. For example, ALD of a dielectric material such as silicon nitride may be performed in the recesses R1 and R2 to fill the substrate recesses SR1′ and SR2′ and the side surfaces of the intermediate semiconductor stacks 10A′-10C′ including the side recesses R3 in the recesses R1 and R2 through ALD. Further, dry etching or wet etching may be performed on the dielectric material based on the gate spacers 151, the hard mask patterns 161 and the mask protection structures 162 as a masking structure such that the side surfaces the inner spacers 116 filled in the side recesses R3 can be vertically aligned or coplanar with the side surfaces of the channel layers 112, 122 and the middle isolation layer 140, and top surfaces of the under-blocking layer 107 can be horizontally aligned or coplanar with the top surface TS of the substrate 101 in the recesses R1 and R2.

Referring to FIG. 2H, a passivation structure 171 may be formed in each of the recesses R1 and R2 to cover the side surfaces of the 1^{st} channel layers 112 and the lower inner spacers 116, and a top surface of the under-blocking layer 107. Further, a 1^{st} blocking layer 133 and a 2^{nd} blocking layer 134 may be conformally formed on an outer surface of each of the intermediate semiconductor stacks 10A′-10C′ except the side surfaces of a lower portion of the middle isolation layer 140, the 1^{st} channel layers 112, and the lower inner spacers 116 that are covered by the passivation structure 171.

The formation of the passivation structure 171 may be performed through, for example, PVD, CVD, PECVD or a combination thereof of a spin-on-glass (SOG) material such as silicon oxide (e.g., SiO, SiO₂, etc.) on each of the intermediate semiconductor stacks 10A′-10C′ from top. Then, the SOG material may be etched down based on the hard mask patterns 161 and the gate spacers 151 so that a top surface of the passivation structure 171 is at a level above a top surface of the uppermost 1^{st} channel layer 112 and below a bottom surface of the lowermost 2^{nd} sacrificial layer 121 to protect the 1^{st} channel layers 112 when the blocking layers 133 and 134 are formed on each of the intermediate semiconductor stacks 10A′-10C′. At this time of etching the SOG material, the mask protection structures 162 which may also be formed of silicon oxide may be removed from top surfaces of the hard mask patterns 161, respectively.

Further, in each of the intermediate semiconductor stacks 10A′-10C′, the 1^{st} blocking layer 133 may be layered on side surfaces of the gate spacer 151, the 2^{nd} channel layers 122, the inner spacers 116 and an upper portion of the middle isolation layer 140 exposed through the recesses R1 and R2, and the 2^{nd} blocking layer 134 may be layered on the 1^{st} blocking layer 182. In each of the recesses R1 and R2, the blocking layers 133 and 134 may be formed to protect the 2^{nd} channel layers 122 when source/drain regions are formed from the 1^{st} channel layers 112 in a later step. The 1^{st} blocking layer 133 may also protect the gate spacer 151 in a later step when the 2^{nd} blocking layer 134 is removed. The formation of the blocking layers 133 and 234 may be performed through, for example, atomic layer deposition (ALD), not being limited thereto.

Referring to FIG. 2I, the passivation structures 171 may be removed to expose the 1^{st} channel layers 112 and the under-blocking layer 107 in the recesses R1 and R2 again, and 1^{st} source/drain regions 135 may be formed in spaces from which the passivation structures 171 are removed. At this time, the 2^{nd} channel layers 122 may still be covered by the blocking layers 134 and 134. Further, 1^{st} protection layers 136 may be formed on top surfaces of the 1^{st} source/drain regions 135 at least to isolate the 1^{st} source/drain regions from the formation of source/drain regions based on the 2^{nd} channel layers and prevent oxidation of the 1^{st} source/drain region from subsequent operations.

The removal of the passivation structure 171 may be performed through, for example, dry etching, wet etching or ashing, and the formation of the 1^{st} source/drain regions 135 may be performed through, for example, epitaxy based on the 1^{st} channel layers 112 of the intermediate semiconductor stacks 10A′-10C′ exposed in the recesses R1 and R2. The 1^{st} protection layer 136 may be formed through, for example, atomic layer deposition (ALD) of silicon nitride (e.g., SiN or Si₃N₄), not being limited thereto.

In this step, the epitaxy forming the 1^{st} source/drain regions 135 may be selectively performed based on only the 1^{st} channel layers 112 because the 2^{nd} channel layers 122 are covered by the blocking layers 133 and 134. Further, when the 1^{st} source/drain region 135 is formed by the epitaxy, a bottom surface of the 1^{st} source/drain region 135 may reach and contact the top surface of the under-blocking layer 107.

Due to the under-blocking layer 107, current flow or leakage from the 1^{st} source/drain regions 135 into the substrate 101 may be prevented or reduced when the intermediate semiconductor stacks 10A′-10C′ are completed as a 3D-stacked semiconductor device. Further, as the under-blocking layer 107 can be formed together with the inner spacers 116, manufacturing simplicity may be achieved.

Referring to FIG. 2J, a 1^{st} isolation structure 141 may be formed on each of the 1^{st} source/drain regions 135 with the 1^{st} protection layer 136 thereon, and the blocking layers 133 and 134 may be removed to expose the side surfaces of the 2^{nd} channel layers 122 of each of the intermediate semiconductor stacks 10A′-10C′ in the recesses R1 and R2. Further, 2^{nd} source/drain regions 145 may be formed based on the 2^{nd} channel layers 122 exposed though the recesses R1 and R2.

The 1^{st} isolation structure 141 may be formed on a top surfaces of the 1^{st} protection layer 136 to isolate the 1^{st} source/drain regions 135 from other circuit elements including 2^{nd} source/drain regions to be formed in a next step. The 1^{st} isolation structure 141 may be formed through, for example, PVD, CVD, PECVD, or their combination, followed by planarization (e.g., CMP) such that a top surface thereof is at a level below the bottom surface of the lowermost 2^{nd} channel layer in each of the intermediate semiconductor stacks 30A′-30C′.

Based on the 1^{st} isolation structure 141, the blocking layers 133 and 134 may be removed from each of the intermediate semiconductor stacks 10A′-10C′ through, for example, dry etching or wet etching except portions thereof at the side surfaces of the middle isolation layer 140.

Further, 2^{nd} source/drain regions 145 may be formed through, for example, epitaxy based on the 2^{nd} channel layers 122 of the intermediate semiconductor stacks 10A′-10C′.

Referring to FIG. 2K, a 2^{nd} protection layer 146 may be formed on each of the intermediate semiconductor stacks 10A′-10C′ to cover at least top surfaces of the 2^{nd} source/drain regions 145, and a 2^{nd} frontside isolation structure 142 may be formed on the 2^{nd} protection layer 146.

The 2^{nd} protection layer 146 may be formed through, for example, atomic layer deposition (ALD) of silicon nitride (e.g., SiN or Si₃N₄), not being limited thereto, to protect each of the 2^{nd} source/drain regions 145 from subsequent operations. The 2^{nd} frontside isolation structure 142 may be formed through, for example, PVD, CVD, PECVD, or a combination thereof, followed by planarization (e.g., CMP) to isolate the 2^{nd} source/drain regions 145 from other circuit elements including the 1^{st} source/drain regions 135.

Referring to FIG. 2L, the hard mask patterns 161 may be removed from each of the intermediate semiconductor stacks 10A′-10C′, and the dummy gate structure 103 along with the 1^{st} barrier layer 118, and the sacrificial layers 111, 121 may also be removed following the removal of the hard mask patterns 161.

The removal of the hard mask patterns 161 may be performed through, for example, ashing, dry etching or wet etching, not being limited thereto. The removal of the dummy gate structures 103, the 1^{st} barrier layer 118, and the sacrificial layers 111, 121 may be performed through, for example, dry etching, wet etching, or a combination thereof, not being limited thereto, using, for example, hydrofluoric acid (HF) to release the channel layers 112 and 122.

Referring to FIG. 2M, a 1^{st} gate structure 115 surrounding the 1^{st} channel layers 112 and a 2^{nd} gate structure 125 surrounding the 2^{nd} channel layers 122 may be formed in the space obtained by the removal of the dummy gate structures 103 and the sacrificial layers 111 and 121.

The formation of the 1^{st} and 2^{nd} gate structures 115 and 125 may be performed through, for example, PVD, CVD, PECVD, ALD, PEALD, or a combination thereof, not being limited thereto.

The 1^{st} gate structure 115 and the 2^{nd} gate structure 125 may include respective work-function metal layers formed of different metals or metal compounds selected from among Cu, Al, titanium (Ti), tantalum (Ta), W, Co, TiN, WN, TiAl, TiAlN, TaN, titanium carbide (TiC), TaC, TiAlC, TaCN, TaSiN, or a combination thereof, not being limited thereto. For example, a combination of TiN and TiC may form a work-function metal layer of a gate structure for an n-type transistor, while TiN without a carbon component may form the same for a p-type transistor.

Based on the above-described process, a 3D-stacked semiconductor device including an under-blocking layer which is the same as or corresponding to the semiconductor device 10 shown in FIG. 1 may be manufactured.

In the above embodiments, an under-blocking layer is formed to enclose a lower portion of a 1^{st} source/drain region disposed below a 2^{nd} source/drain region in a 3D-stacked semiconductor device. However, the disclosure is not limited thereto, and the under-blocking layer may be formed to enclose a lower portion of a source/drain region of a single-stack 3D-stacked semiconductor device, according to one or more embodiments. Further, although the above embodiments provide the 3D-stacked semiconductor device 10 in which two nanosheet transistors are formed on a 1^{st} stack and a 2^{nd} stack, the embodiment may also apply to a 3D-stacked semiconductor device in which at least one of a transistor on the 1^{st} stack and a transistor on the 2^{nd} stack is a different type of transistor such as FinFET, according to one or more embodiments.

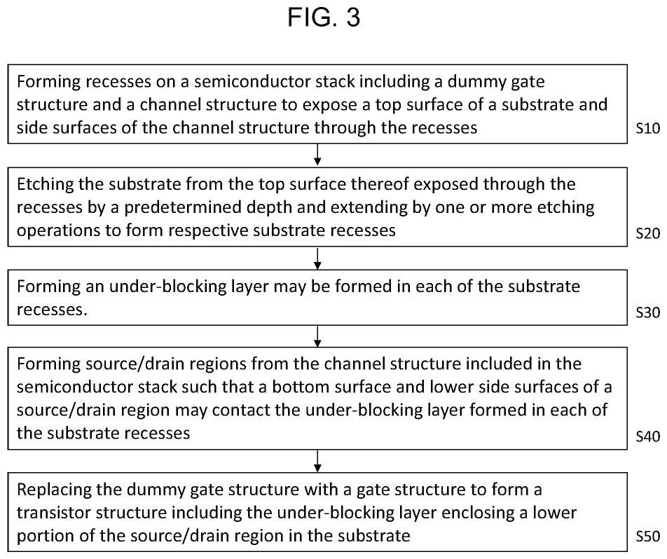

FIG. 3 illustrates a flowchart of manufacturing a semiconductor device including an under-blocking layer formed on a source/drain region, according one or more embodiments. The semiconductor device manufactured based on the flowchart of FIG. 3 may apply to manufacturing the 3D-stacked semiconductor device 10 shown in FIG. 1 and correspond to FIGS. 2A-2M.

In step S10, a couple of recesses may be formed on a semiconductor stack including a dummy gate structure and a channel structure to expose a top surface of a substrate and side surfaces of the channel structure through the recesses. See FIGS. 2A and 2B

The recesses formed in this step may provide a space in which source/drain regions grow from the channel structure including one or more channel layers such as nanosheet layers for a nanosheet transistor or a fin structure for a FinFET.

In step S20, the substrate may be etched down from the top surface thereof exposed through the recesses by a predetermined depth and extended by one or more etching operations to form respective substrate recesses. See FIGS. 2C-2F.

The etching operations may be performed such that each of the substrate recesses obtained thereby may have a cut-diamond or sigma shape in the substrate below a level of a bottom surface of the dummy gate structure which may contact a top surface of the substrate. The cut-diamond or sigma shape of the substrate recess may be formed through, for example, dry etching of the substrate from a top surface thereof by a predetermined depth to form an initial substrate recess, and wet etching on the initial substrate recess in the (100) plane direction and the (110) plane direction.

In step S30, an under-blocking layer may be formed in each of the substrate recesses. See FIG. 2G.

The under-blocking layer may be formed along with inner spacers isolating a gate structure that is to replace the dummy gate structure in a later step from the source/drain regions. The under-blocking layer and the inner spacers may be formed of the same material such as silicon nitride, not being limited thereto.

In step S40, source/drain regions may be formed from the channel structure included in the semiconductor stack such that a bottom surface of a source/drain region may contact a top surface of the under-blocking layer formed in each of the substrate recesses obtained in step 20. See FIG. 2H-2J.

The under-blocking layer may have a 1^{st} portion, a 2^{nd} portion and a 3^{rd} portion. The 1^{st} portion may edge into the substrate from the bottom surface of the source/drain region such that a length of the 1^{st} portion in the D1 direction decreases in the downward D3 direction. The 2^{nd} portion may edge into the substrate such that a thickness of the 2^{nd} portion decreases in the leftward D1 direction from the lower portion of the the source/drain region. The 3^{rd} portion may edge into the substrate such that a thickness of the 3^{rd} portion decreases in the rightward D1 direction from the lower portion of the source/drain region.

In step S50, the dummy gate structure may be replaced by a gate structure to form a transistor structure including the under-blocking layer enclosing a lower portion of the source/drain region in the substrate. See FIGS. 2K-2M

FIG. 4 is a schematic block diagram illustrating an electronic device including at least one of the 3D-stacked semiconductor devices shown in FIGS. 1 and 2A-2M and the semiconductor device described in reference to FIG. 3, according to one or more embodiments.

Referring to FIG. 4, an electronic device 1000 may include at least one processor 1100, a communication module 1200, an input/output module 1300, a storage 1400, and a buffer random access memory (RAM) module 1500. The electronic device 1000 may be a mobile device such as a smartphone or a tablet computer, not being limited thereto, according to embodiments.

The processor 1100 may include a central processing unit (CPU), a graphic processing unit (GPU) and/or any other processors that control operations of the electronic device 1000. The communication module 1200 may be implemented to perform wireless or wire communications with an external device. The input/output module 1300 may include at least one of a touch sensor, a touch panel a key board, a mouse, a proximate sensor, a microphone, etc. to receive an input, and at least one of a display, a speaker, etc. to generate an output signal processed by the processor 1100. The storage 1400 may be implemented to store user data input through the input/output module 1300, the output signal, etc. The storage 1400 may be an embedded multimedia card (eMMC), a solid state drive (SSD), a universal flash storage (UFS) device, etc.

The buffer RAM module 1500 may temporarily store data used for processing operations of the electronic device 1000. For example, the buffer RAM 1500 may include a volatile memory such as double data rate (DDR) synchronous dynamic random access memory (SDRAM), low power double data rate (LPDDR) SDRAM, graphics double data rate (GDDR) SDRAM, Rambus dynamic random access memory (RDRAM), etc.

Although not shown in FIG. 4, the electronic device 1000 may further include at least one sensor such as an image sensor.

At least one component in the electronic device 1000 may be formed based on at least one of the 3D-stacked semiconductor devices shown in FIGS. 1 and 2A-2M and the semiconductor device described in reference to FIG. 3.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A semiconductor device comprising:
a substrate;
a 1^{st} source/drain region above the substrate; and
an under-blocking layer below the 1^{st} source/drain region,
wherein the under-blocking layer faces the substrate, and comprises one or more insulation materials.

2. The semiconductor device of claim 1, wherein the under-blocking layer is disposed below a level of a top surface of the substrate.

3. The semiconductor device of claim 1, wherein the under-blocking layer comprises:
a 1^{st} portion below the 1^{st} source/drain region, vertically overlapping the 1^{st} source/drain region;
a 2^{nd} portion at a 1^{st} side of the 1^{st} source/drain region, not vertically overlapping the 1^{st} source/drain region; and
a 3^{rd} portion at a 2^{nd} side of the 1^{st} source/drain region, not vertically overlapping the 1^{st} source/drain region.

4. The 3D-stacked semiconductor device of claim 3, wherein the 1^{st} portion vertically edges into the substrate such that a length of the 1^{st} portion decreases in a downward direction from the 1^{st} source/drain region,
wherein the 2^{nd} portion laterally edges into the substrate such that a thickness of the 2^{nd} portion decreases in a 1^{st} lateral direction from the 1^{st} source/drain region, and
wherein the 3^{rd} portion laterally edges into the substrate such that a thickness of the 3^{rd} portion decreases in a 2^{nd} lateral direction from the 1^{st} source/drain region.

5. The semiconductor device of claim 1, wherein the under-blocking layer is configured to prevent or reduce current flow from the 1^{st} source/drain region to the substrate.

6. The semiconductor device of claim 1, further comprising:
a channel structure connected to the 1^{st} source/drain region; and
a gate structure configured to control the channel structure,
wherein a top surface of the under-blocking layer is at or below a level of a bottom surface of the gate structure.

7. The semiconductor device of claim 1, further comprising:
a channel structure connected to the 1^{st} source/drain region;
a gate structure configured to control the channel structure; and
an inner spacer between the gate structure and the 1^{st} source/drain region,
wherein the top surface of the under-blocking layer is at or below a level of a bottom surface of the inner spacer.

8. The semiconductor device of claim 1, further comprising a 2^{nd} source/drain region above the 1^{st} source/drain region.

9. The 3D-stacked semiconductor device of claim 1, wherein the under-blocking layer has a greater length than the 1^{st} source/drain region in a channel-length direction.

10. The 3D-stacked semiconductor device of claim 1, further comprising:
a channel structure connected to the 1^{st} source/drain region;
a gate structure configured to control the channel structure; and
an inner spacer between the gate structure and the 1^{st} source/drain region,
wherein the under-blocking layer and the inner spacer are formed of the same material.

11. A semiconductor device comprising:
a substrate;
a 1^{st} source/drain region above the substrate; and
an under-blocking layer configured to prevent or reduce current flow from the 1^{st} source/drain region to the substrate,
wherein the under-blocking layer comprises one or more insulation materials.

12. The semiconductor device of claim 11, wherein the under-blocking layer is disposed below the 1^{st} source/drain region to face the substrate.

13. The semiconductor device of claim 11, wherein the under-blocking layer comprises:
a 1^{st} portion below the 1^{st} source/drain region, vertically overlapping the 1^{st} source/drain region;
a 2^{nd} portion at a 1^{st} side of the 1^{st} source/drain region, not vertically overlapping the 1^{st} source/drain region; and
a 3^{rd} portion at a 2^{nd} side of the 1^{st} source/drain region, not vertically overlapping the 1^{st} source/drain region.

14. The semiconductor device of claim 11, wherein the under-blocking layer is formed in the substrate.

15. The semiconductor device of claim 11, further comprising a 2^{nd} source/drain region above the 1^{st} source/drain region.

16. A method of manufacturing a semiconductor device, comprising:
forming a substrate recess in a substrate;
forming an under-blocking layer in the substrate recess; and
forming a source/drain region on the under-blocking layer.

17. The method of claim 16, wherein the forming the substrate recess comprises:
forming an initial recess in the substrate; and
etching the substrate from the initial recess in a (100) plane direction and a (110) plane direction.

18. The method of claim 16, wherein the under-blocking layer is formed to comprise:
a 1^{st} portion below the 1^{st} source/drain region, vertically overlapping the 1^{st} source/drain region;
a 2^{nd} portion at a 1^{st} side of the 1^{st} source/drain region, not vertically overlapping the 1^{st} source/drain region; and
a 3^{rd} portion at a 2^{nd} side of the 1^{st} source/drain region, not vertically overlapping the 1^{st} source/drain region.

19. The method of claim 16, wherein the 1^{st} portion is formed to vertically edge into the substrate such that a length of the 1^{st} portion decreases in a downward direction from the 1^{st} source/drain region,
wherein the 2^{nd} portion is formed to laterally edge into the substrate such that a thickness of the 2^{nd} portion decreases in a 1^{st} lateral direction from the 1^{st} source/drain region, and
wherein the 3^{rd} portion is formed to laterally edge into the substrate such that a thickness of the 3^{rd} portion decreases in a 2^{nd} lateral direction from the 1^{st} source/drain region.

20, The method of claim 16, further comprising:
forming a channel structure to which the 1^{st} source/drain region is to be connected; and
forming a gate structure to surround the channel structure,
wherein the under-blocking layer is formed such that a top surface thereof is at or below a level of a bottom surface of the gate structure.
